(19) United States
(12) Patent Application Publication
(10) Pub. No.: US 2026/0297730 A1
(43) Pub. Date: Oct. 1, 2026

(54) TOPOLOGY-SELECTIVE DEPOSITION METHOD AND STRUCTURE FORMED USING SAME

(71) Applicant: ASM IP Holding B.V., Almere (NL)

(72) Inventors: William George Petro, Scottsdale, AZ (US); Paul Ma, Scottsdale, AZ (US); Jereld Lee Winkler, Gilbert, AZ (US)

(21) Appl. No.: 19/577,554

(22) Filed: Mar. 25, 2026

Related U.S. Application Data
(60) Provisional application No. 63/780,132, filed on Mar. 28, 2025.

(51) Int. Cl. C23C 16/04; C23C 16/06

(52) U.S. Cl. CPC C23C 16/045; C23C 16/042; C23C 16/06

(57) ABSTRACT

A topology-selective deposition method is disclosed. An exemplary method includes providing blocking molecules within a reaction chamber and providing a precursor within the reaction chamber, wherein the blocking molecules inhibit deposition on a top surface of the substrate, relative to a surface within a gap on the substrate surface.

### CROSS-REFERENCE TO RELATED APPLICATIONS

This application is a nonprovisional of, and claims priority to and the benefit of, U.S. Provisional Patent Application No. 63/780,132, filed Mar. 28, 2025 and entitled “TOPOLOGY-SELECTIVE DEPOSITION METHOD AND STRUCTURE FORMED USING SAME,” which is hereby incorporated by reference herein.

### FIELD

The present disclosure generally relates to gas-phase deposition methods. More particularly, the disclosure relates to methods of forming structures that include a topology-selectively deposited material.

### BACKGROUND OF THE DISCLOSURE

During the formation of devices, such as semiconductor devices, it is often desirable to form patterned features on a surface of a substrate. Typically, to form patterned features, a layer of material is deposited, the deposited layer is then patterned using, for example, photolithography, and then the film is etched to form features including the material.

As device features continue to decrease in size, it becomes increasingly difficult to pattern and etch material layers to form features of desired dimensions. And, lithography and etch steps can increase costs associated with device manufacturing and increase an amount of time required for device fabrication. Furthermore, in some cases, it may be desirable to form or deposit material only in certain topology-selective regions on a surface of a substrate. For example, it may be desirable to topologically selectively deposit material only at a bottom of a feature, such as a via or a trench. In such cases, typical deposition, pattern, and etch techniques may not be suitable—particularly as a size of the features continues to decrease.

Accordingly, improved methods for topologically selective formation of materials are desired.

Any discussion of problems and solutions described in this section has been included in this disclosure solely for the purposes of providing a context for the present disclosure. Such should not be taken as an admission that any or all of the discussion is prior art or was known at the time the invention was made.

### SUMMARY OF THE DISCLOSURE

Various embodiments of the present disclosure relate to topology-selective deposition methods, to structures formed using the methods, and to systems for performing the methods. While the ways in which various embodiments of the present disclosure address drawbacks of prior methods and structures are discussed in more detail below, in general, embodiments of the disclosure provide improved methods of topo-selective methods that include using blocking molecules to inhibit deposition of material on a top surface of a feature or substrate, relative to a bottom surface of the feature.

In accordance with embodiments of the disclosure, a topology-selective deposition method includes providing a substrate within a reaction chamber, providing blocking molecules within the reaction chamber, and providing a precursor (e.g., within the reaction chamber). The substrate includes one or more gaps on a surface thereof. At least one gap includes a gap opening width and a gap height. The blocking molecules have a blocking molecule dimension (e.g., diameter or width) greater than the gap opening width. The precursor includes precursor molecules that have a precursor dimension less than the opening width. At least in part due to their larger size, the blocking molecules inhibit deposition on a top surface of the substrate, relative to a surface within the gap. And, due at least in part to their smaller size, the precursor molecules are able to reach within a feature—e.g., a bottom of the feature to, e.g., fill the feature from a bottom surface upwards. In accordance with examples of these embodiments, the method comprises a cyclical deposition process. The cyclical deposition process can include one or more cycles, wherein at least one cycle includes providing blocking molecules and providing the precursor. The cycle can further include a purge step between providing blocking molecules and providing the precursor. Additionally or alternatively, the cycle can further include providing a reactant to the reaction chamber. The method and/or cycle can further include removing blocking molecules or derivatives thereof from the surface of the substrate. The blocking molecules or derivatives can be chemisorbed or physioabsorbed. In accordance with examples, the step of removing blocking molecules or derivatives thereof can include providing a removal agent to the reaction chamber to facilitate removal of the blocking molecules or derivatives thereof, particularly when the blocking molecules or derivatives thereof are chemisorbed onto the surface of the substrate. The deposited material can be or include, for example, a metal.

In accordance with additional embodiments of the disclosure, a structure includes topology-selectively deposited material. The topology-selectively deposited material can be deposited using a method as described herein.

In accordance with further examples of the disclosure, a system is provided. The system can be configured to perform a method as described herein and/or to form a structure as described herein.

For the purpose of summarizing the embodiments and the advantages achieved over the prior art, certain objects and advantages of the invention may have been described herein above. Of course, it is to be understood that not necessarily all such objects or advantages may be achieved in accordance with any particular embodiment. Thus, for example, those skilled in the art will recognize that the certain embodiments may be embodied or carried out in a manner that achieves or optimizes one advantage or group of advantages as taught or suggested herein without necessarily achieving other objects or advantages as may be taught or suggested herein.

All of these embodiments are intended to be within the scope of the disclosure. These and other embodiments will become readily apparent to those skilled in the art from the following detailed description of certain embodiments having reference to the attached figures, the disclosure not being limited to any particular embodiment(s) disclosed.

### BRIEF DESCRIPTION OF THE DRAWING FIGURES

A more complete understanding of exemplary embodiments of the present disclosure can be derived by referring to the detailed description and claims when considered in connection with the following illustrative figures.

FIG. 1 illustrates a topology-selective deposition method in accordance with at least one embodiment of the disclosure.

FIGS. 2-6 illustrate structures in accordance with examples of the disclosure.

FIG. 7 illustrates a system in accordance with yet further examples of the disclosure.

FIG. 8 illustrates another system in accordance with yet further examples of the disclosure.

It will be appreciated that elements in the figures are illustrated for simplicity and clarity and have not necessarily been drawn to scale. For example, the dimensions of some of the elements in the figures may be exaggerated relative to other elements to help improve understanding of illustrated embodiments of the present disclosure.

### DETAILED DESCRIPTION OF EXEMPLARY EMBODIMENTS

Although certain embodiments and examples are disclosed below, it will be understood by those in the art that the invention extends beyond the specifically disclosed embodiments and/or uses of the invention and obvious modifications and equivalents thereof. Thus, it is intended that the scope of the invention disclosed should not be limited by the particular disclosed embodiments described below.

The present disclosure generally relates to topology-selective deposition methods, structures formed using the methods, and systems that can be used to perform the methods and/or form the structures. As described in more detail below, exemplary methods can be used to form device structures suitable for various applications, including forming electronic devices. For example, exemplary methods can be used to form features that include topology-selective deposited material suitable for selectively depositing a metal-containing material within or on a bottom of a feature. The material can be deposited within features in a relatively void- and seam-free manner.

In this disclosure, gas may include material that is a gas at normal temperature and pressure, a vaporized solid and/or a vaporized liquid, and may be constituted by a single gas or a mixture of gases, depending on the context. A gas other than the process gas, e.g., a gas introduced without passing through a gas distribution assembly, such as a showerhead, other gas distribution device, or the like, may be used for, e.g., sealing the reaction space, and may include a seal gas, such as a noble or other inert gas. The term inert gas refers to a gas that does not take part in a chemical reaction to an appreciable extent. In some cases, the terms precursor and reactant can be used interchangeably.

As used herein, the term substrate can refer to any underlying material or materials that may be used to form, or upon which, a device, a circuit, or a film may be formed. A substrate can include a bulk material, such as silicon (e.g., single-crystal silicon), other Group IV materials, such as germanium, or compound semiconductor materials, such as GaAs, and can include one or more layers overlying or underlying the bulk material. Further, the substrate can include various structures, such as recesses, lines, and the like formed within or on at least a portion of a layer of the substrate. By way of examples, a substate can include a feature, such as a gap, via, trench or the like (generally referred to as a gap or a feature), that includes a distal surface and a proximal surface. It shall be understood that a distal surface of a gap can refer to a portion of the gap, which is relatively far removed from a substrate's surface, and that the proximal portion of a gap feature refers to a part of the gap feature which is closer to the substrate's surface compared to the distal/lower/deeper portion of the gap feature. The proximal surface of the gap can coincide with the surface of the substrate.

As used herein, the term cyclical deposition may refer to the sequential introduction of precursors/reactants into a reaction chamber to deposit a layer over a substrate and includes processing techniques, such as atomic layer deposition (ALD), molecular layer deposition (MLD), and cyclical chemical vapor deposition (CCVD).

As used herein, the terms ALD and MLD may refer to a vapor deposition process in which deposition cycles, typically a plurality of consecutive deposition cycles, are conducted in a process chamber. Generally, during each cycle, a precursor is chemisorbed to a deposition surface (e.g., active sites on the surface), forming about a monolayer or sub-monolayer of material that does not readily react with additional precursor (i.e., a self-limiting reaction). Thereafter, in some cases, a reactant or activated species formed using the reactant may subsequently be introduced into the process chamber for use in converting or reacting with the chemisorbed precursor to form the desired material on the deposition surface. Further, purging steps can also be utilized during each cycle to remove excess precursor from the process chamber and/or remove excess reactant and/or reaction byproducts from the process chamber after conversion of the chemisorbed precursor.

As used herein, the term CCVD may refer to any process wherein a substrate is sequentially exposed to two or more volatile precursors, which react and/or decompose on a substrate to produce a desired deposition. A cycle can include pulsing one or more of the reactant, the precursor, a plasma power, or the like.

In some embodiments, film refers to a layer extending in a direction perpendicular to a thickness direction to cover an entire target or concerned surface, or simply a layer covering a target or concerned surface. In some embodiments, layer refers to a structure having a certain thickness formed on a surface or a synonym of film or a non-film structure. A layer can be continuous or noncontinuous. A film or layer may be constituted by a discrete single film or layer having certain characteristics or multiple films or layers, and a boundary between adjacent films or layers may or may not be clear and may or may not be established based on physical, chemical, and/or any other characteristics, formation processes or sequences, and/or functions or purposes of the adjacent films or layers. The terms film and layer can be used interchangeably.

In this disclosure, continuously can refer to one or more of without breaking a vacuum, without interruption as a timeline, without any material intervening step, without changing treatment conditions, immediately thereafter, as a next step, or without an intervening discrete physical or chemical structure between two structures other than the two structures in some embodiments. For example, a reactant and/or a noble gas can be supplied continuously during two or more steps and/or deposition cycles of a method.

As used herein, the term purge may refer to a procedure in which an inert or substantially inert gas is provided to a reactor chamber in between pulses of other (e.g., reactant or precursor) gases and/or after a plasma power pulse. For example, in some cases, a purge may be provided between a precursor pulse and a reactant pulse, thereby avoiding or at least reducing gas phase interactions between the precursor and the reactant. It shall be understood that a purge can be effected either in time or in space or both. For example, in the case of temporal purges, a purge step can be used, e.g., in the temporal sequence of providing a precursor to a reactor chamber and then providing a purge gas to the reactor chamber, wherein the substrate on which a layer is deposited does not move. In the case of spatial purges, a purge step can take the form of moving a substrate from a first location to which a first precursor is supplied, through a purge gas curtain, to a second location to which a reactant or the precursor is supplied. In some cases, a reactant that is not excited by a plasma can be used to purge the reactor chamber.

As used herein, the term overlap can mean coinciding with respect to time and within a reaction chamber. For example, with regard to gas pulse periods, such as precursor pulse periods and reactant pulse periods, two or more gas pulse periods can overlap when gases from the respective pulse periods are within the reaction chamber or provided to the reaction chamber for a period of time.

In this disclosure, any two numbers of a variable can constitute a workable range of the variable, and any ranges indicated may include or exclude the endpoints. Additionally, any values of variables indicated (regardless of whether they are indicated with “about” or not) may refer to precise values or approximate values and include equivalents, and may refer to average, median, representative, majority, or the like. Further, in this disclosure, the terms including, constituted by and having can refer independently to typically or broadly comprising, comprising, consisting essentially of, or consisting of in some embodiments. In accordance with aspects of the disclosure, any defined meanings of terms do not necessarily exclude ordinary and customary meanings of the terms.

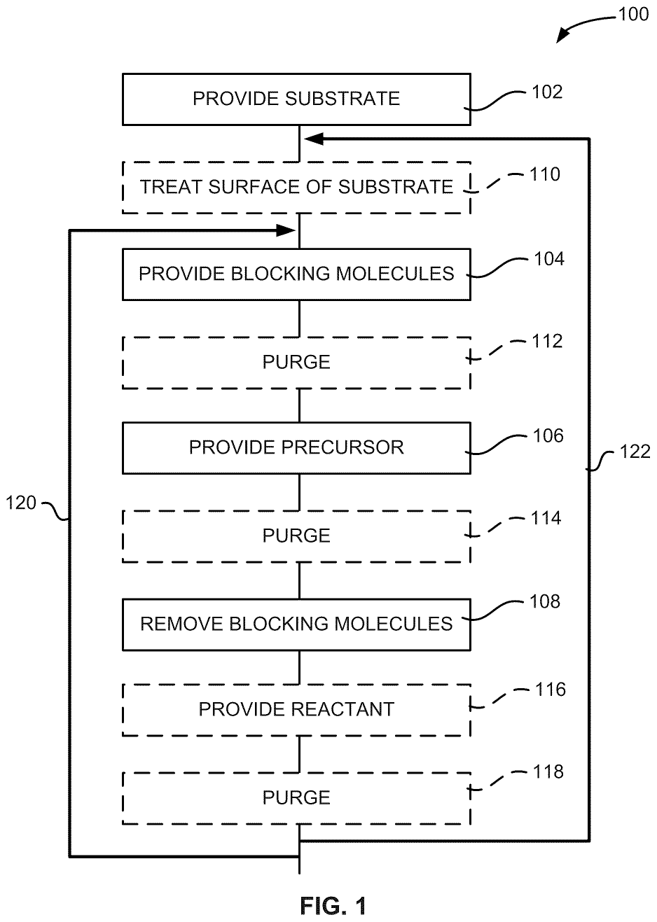

Turning now to the figures, FIG. 1 illustrates a topology-selective deposition method 100 in accordance with at least one embodiment of the disclosure. Method 100 includes the steps of providing a substrate (step 102), providing blocking molecules (step 104), providing a precursor (step 106), and removing blocking molecules (step 108). Method 100 can also include one or more of a treatment (step 110), providing a reactant (step 116), and/or one or more purge steps (steps 112, 114, 118).

During step 102, a substrate is provided, e.g., into a reaction chamber of a reactor. In accordance with examples of the disclosure, the reaction chamber can form part of a cyclical deposition reactor, such as an ALD, MLD, or CCVD reactor. Various steps of method 100 can be performed within a single reaction chamber or can be performed in multiple reaction chambers, such as reaction chambers of a reactor or of a cluster tool. Optionally, a reactor including the reaction chamber can be provided with a heater to activate the reactions by elevating the temperature of one or more of the substrate, the reaction chamber wall, and/or the reactants/precursors.

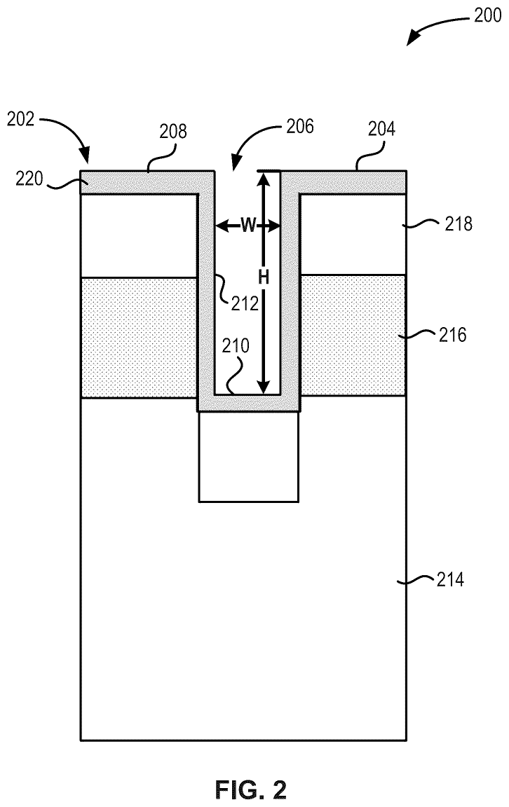

An exemplary substrate 200 provided during step 102 is illustrated in FIG. 2. As illustrated, substrate 200 includes one or more patterned structures 202 on a surface 204 of substrate 200. Patterned structure 202 includes a gap 206 comprising a proximal surface 208, a distal surface 210, and a sidewall 212. Gap 206 can be formed, for example, as a via, between lines or protrusions, or the like. Thus, in some cases, sidewall 212 can span a gap, and in other cases, a gap can include a plurality of sidewalls. As illustrated, gap 206 includes a gap opening width W and a gap height H.

In the illustrated example, substrate 200 includes a bulk material or layer 214 and can include additional layers 216, 218 thereon. Layer 214 can be or include insulating material, such as silicon oxide. Layers 216, 218 can be or include additional insulating layers, such as silicon oxide and/or silicon nitride. For example, layer 216 can be or include silicon nitride and layer 218 can be or include silicon oxide. Substrate 200 can also include a liner or barrier layer 220 formed within gap 206 and, in some cases, on a least a portion of layer 218. Barrier or liner layer 220 can be or include, for example, a transition metal nitride, such as TiN, TaN, WN, combinations thereof, or the like. Other structures, including a gap with other layers, are contemplated by the present disclosure.

During step 102, the substrate can be brought to a desired temperature and pressure for step 104 and/or step 110. By way of examples, a temperature (e.g., of a substrate or a substrate support) within a reaction chamber can be between about 25° C. and about 300° C. or about 50° C. and about 200° C. A pressure within the reaction chamber can be about 0.1 to about 10 Torr or about 10 to about 760 Torr.

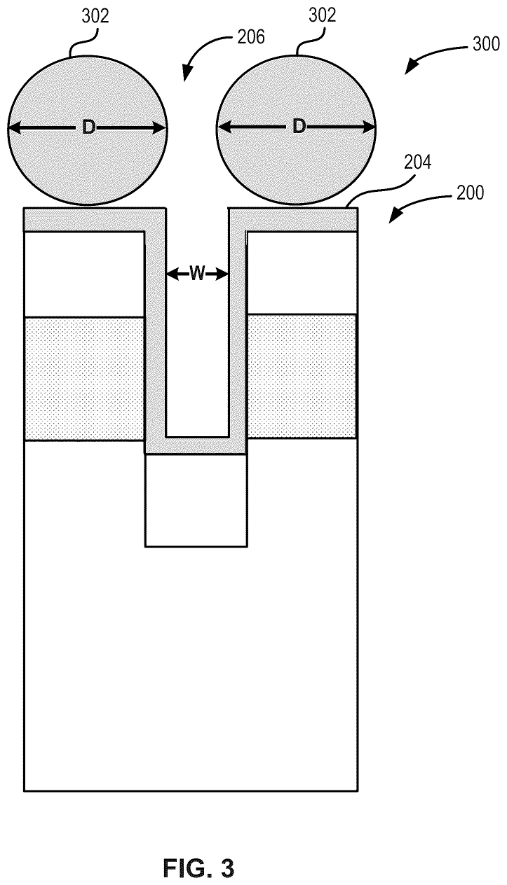

During step 104, blocking molecules are provided within the reaction chamber. FIG. 3 illustrates blocking molecules 302 that are provided during step 104 and that may eventually chemisorb or physioadsorb onto surface 204 of substrate 200. Blocking molecules 302 are configured to prevent or mitigate adsorption of precursor molecules on surface 204, while allowing the precursor molecules to adsorb onto or react with a surface within gap 206 (e.g., distal surface 210 and/or sidewall 212). As illustrated, blocking molecules 302 may suitably have a blocking molecule dimension (e.g., diameter, height, width, length, or the like) D greater than the gap opening width W. In accordance with further examples, a plurality or dimensions of blocking molecule 302 are greater than W, such that blocking molecules 302 are substantially inhibited or prevented from entering gap 206.

Exemplary molecules suitable for use as blocking molecules include molecules having dimensions are greater than 2×, 5× or 10× times W. Additionally or alternatively, one or more blocking molecule dimensions can be greater than 2×, 10×, 20× or 25× a cross-sectional dimension of an opening. The blocking molecules can be provided to the reaction chamber in gas form and, in some cases, can form a mist on or near the surface of the substrate.

In accordance with various examples of the disclosure, the blocking molecules can be or include a surfactant. In some cases, the blocking molecules comprise a carbene. The carbene can be or include a heterocyclic carbene, such as an N-heterocyclic carbene. Exemplary N-heterocyclic carbenes suitable for use during step 104 can be represented by the formula

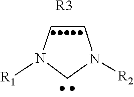

where R₃ is a cyclic group and where each R₁ and R₂ is independently selected from H or a C1-C16 alkyl group. In some cases, R₁ and/or R₂ and/or R₃ can be or include a (e.g., C4-C8 or C5-C12) cyclic group. In accordance with additional examples, the blocking molecules comprise an alkyl-terminated polyethylene glycol. Exemplary alkyl-terminated polyethylene glycols suitable for use in step 104 include compounds represented by the formula

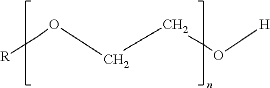

where n ranges from about 50 to about 2000, and where R is a C1-C10 linear or branched or cyclic hydrocarbon.

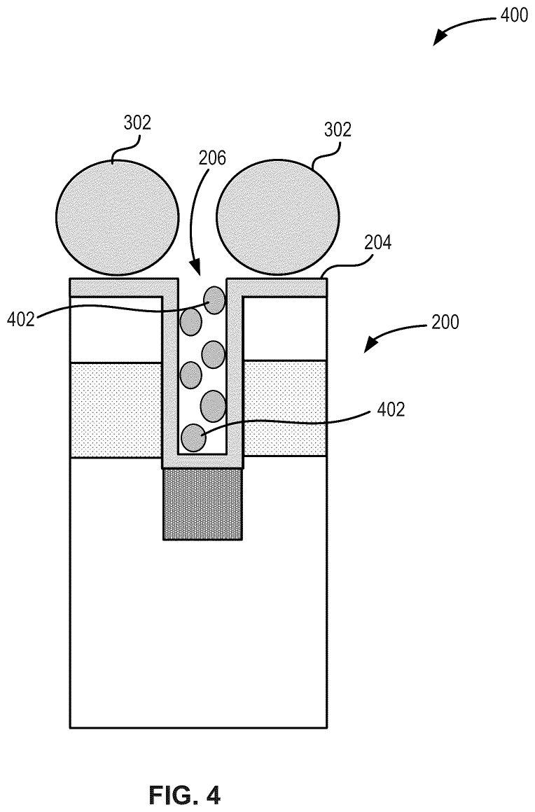

During step 106, a precursor is provided to the reaction chamber. In some cases, step 106 can overlap with step 104. In some cases, steps 104 and 106 can substantially overlap, such that the precursor and the blocking molecules are provided to the reaction chamber at substantially the same time. In some cases, the precursor and the blocking molecules are provided to the reaction chamber together—e.g., the blocking molecules and the precursor can be premixed prior to entering the reaction chamber. In other cases, steps 104 and 106 can be separated—e.g., via a purge step. FIG. 4 illustrates a structure 400, including precursor molecules 402 within gap 206.

In accordance with examples of the disclosure, the precursor includes molecules having one or more precursor dimensions less than the gap opening width. This allows the precursor molecules to flow within the gap (e.g., gap 206).

The precursor provided during step 106 can be or include any suitable precursor. In accordance with examples of this disclosure, the precursor includes a metal precursor that includes a metal. Exemplary metals include transition metals, such as Mo, W, Co, Ru, Pt, Rh, or Ir. Exemplary metal precursors can include metal halide compounds, metal organic compounds, and/or organometallic compounds. Exemplary metal halides include metal chlorides, metal fluorides, metal bromides, or metal chlorides. An organometallic precursor is herein meant to refer to a (e.g., transition) metal compound comprising a (e.g., transition) metal atom and an organic (e.g., hydrocarbon) ligand, wherein the transition metal atom is directly bonded to a carbon atom. In some embodiments, an organometallic precursor comprises only one or more metals, carbon and hydrogen. In other words, an organometallic precursor does not contain oxygen, nitrogen or other additional elements. In some embodiments, the organometallic precursor comprises at least two hydrocarbon ligands. In some embodiments, the organometallic precursor comprises at least three hydrocarbon ligands. In some embodiments, the organometallic precursor comprises four hydrocarbon ligands. In some embodiments, the organometallic precursor comprises a hydrocarbon ligand and a hydride ligand. In some embodiments, the organometallic precursor comprises a hydrocarbon ligand and two or more hydride ligands. In some embodiments, the organometallic precursor comprises two hydrocarbon ligands and two hydride ligands. Hydrocarbon ligands as described herein can be or include, for example, C1-C10 hydrocarbons. In some embodiments, the metal precursor comprises one or more cyclic portions. For example, the transition metal precursor may comprise one or more benzene rings. In some embodiments, the metal precursor comprises two benzene rings. One or both benzene rings may comprise (e.g., C1-C6) hydrocarbon substituents. In some embodiments, each benzene ring of the transition metal precursor comprises an alkyl substituent. An alkyl substituent may be a methyl group, an ethyl group, or a linear or branched alkyl group comprising three, four, five or six carbon atoms. For example, the alkyl substituent of the benzene ring may be an n-propyl group or an iso-propyl group. Further, the alkyl substituent may be an n-, iso-, tert- or sec- form of a butyl, pentyl or hexyl moiety. In some embodiments, the transition metal precursor comprises a cyclopentadienyl (Cp) ligand. For example, the transition metal precursor may comprise, consist essentially of, or consist of MCp₂Cl₂ or MCp₂H₂, M(iPrCp)₂Cl₂, M(iPrCp)₂H₂, M(EtCp)₂H₂, wherein M represents, for example, a transition metal, iPr represents an isopropyl group, and Et represents an ethyl group. Exemplary metal organic compounds include molecules comprising a metal atom and an organic ligand bonded to the metal though a nitrogen, oxygen, sulfur, or phosphorus atom. Exemplary organic ligands for a metalorganic precursor include dialkylamido ligands, alkylimido ligands, N,N′-dialkylamidinate ligands, N,N′-dialkyldiazadienyl ligands, alkoxide ligands, beta-diketonate ligands, alkylthiolate ligands, and alkyl- or aryl-substituted phosphine ligands.

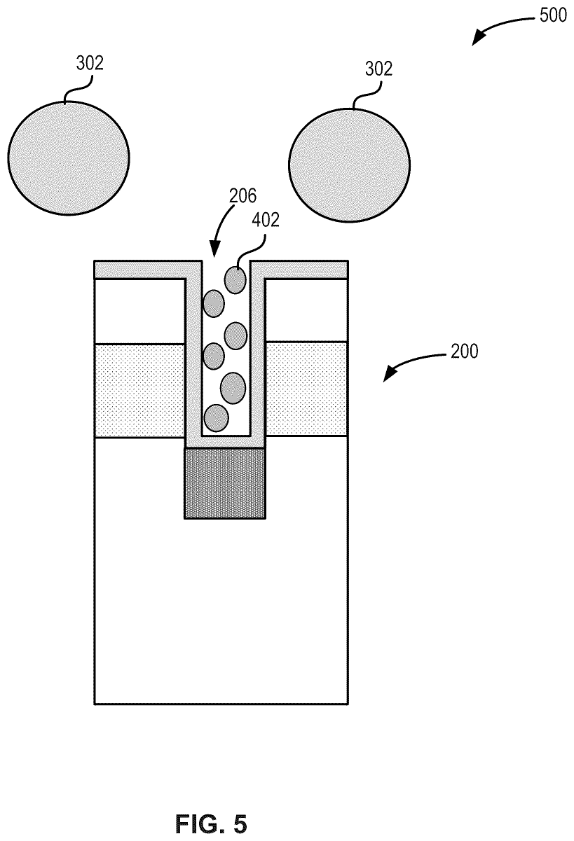

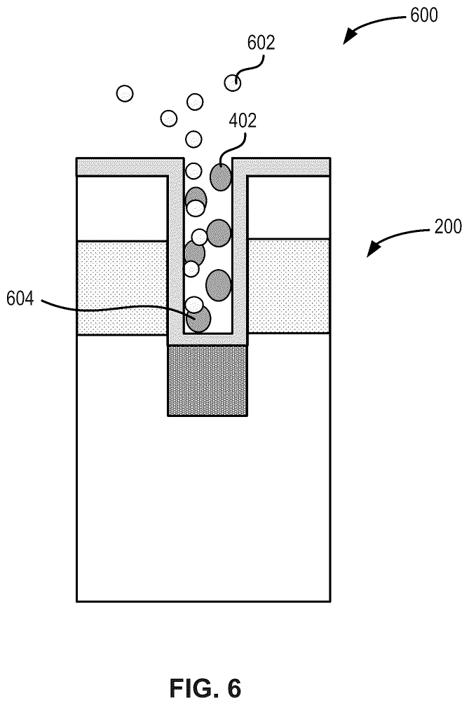

During step 108, the blocking molecules are removed from the reaction chamber and/or the surface of the substrate. FIG. 5 illustrates a structure 500, in which the blocking molecules or derivatives thereof are removed and wherein the precursor molecules or derivative thereof remain on one or more surfaces within gap 206.

If the blocking molecules are physioabsorbed to the surface of the substrate, the blocking molecules can be removed using a purge step, such as a purge step described herein. If the blocking molecules are chemisorbed on the substrate surface, step 108 can include providing a removal agent to the reaction chamber. Exemplary removal agents include, e.g., C1-C10 linear or branched or cyclic alcohols and/or C1-C10 linear or branched or cyclic diols. Particular examples of removal agents include H₂O or O₃. In these cases, H₂O can be released. The H₂O can reinstate a desired terminal group on the substrate surface for subsequent processing—e.g., one or more steps of method 100 or other processes. Water or ozone can additionally or alternatively be used as a removal agent.

In some cases, step 108 can be performed at a temperature greater than a temperature during step 106 of providing the precursor. For example, a temperature during step 108 may be about 25° C. to about 100° C. or about 30° C. to about 75° C. higher during step 108, compared to step 106.

As illustrated, method 100 can also include step 116 of providing a reactant 602 to the reaction chamber. Step 116 can overlap with one or more of steps 104 and/or 106 or can be separated from step 104 and/or 106—e.g., via a purge. In some cases, a reactant may be continuously flowed during method 100.

During step 116, reactant 602 that is provided can react with precursor molecules provided during step 106 or derivatives thereof to form material 604 within gap 206. Exemplary reactants suitable for use during step 116 include reducing agents, such as H₂, ammonia, hydrazine, C1-C4 alkyl substituted hydrazines, or the like. Step 116 can be performed before steps 106 or 108 or after or overlapping with steps 106, 108.

Exemplary materials that are formed using method 100 include metal. The metal can be or include, for example, one or more of a transition metal or a rare earth metal.

As further illustrated in FIG. 1, method 100 can include step 110 of treating the surface within the gap. Step 110 can be performed before a deposition cycle and/or can be performed during one or more deposition cycles.

Exemplary treating steps can include, for example, an Ar/H₂ remote, direct, or indirect plasma treatment.

As noted herein, method 100 can also include one or more purge steps, such as steps 112, 114, and/or 118. The purge steps can include a temporal and/or special purge as noted herein. In some cases, a reactant can be flowed during a purge process. As illustrated, method 100 can include one or more of purge step 112 between the providing blocking molecules and the providing the precursor, purge step 114 between the providing the precursor and removing blocking molecules, and/or purge step 118 after providing the reactant.

As noted above, method 100 can be a cyclical deposition process. A cycle of the cyclical deposition process can include providing blocking molecules step 104 and providing the precursor step 106. For example, a cycle can include steps 104-118 or a subset thereof (loop 120) or can include steps 110-118 or a subset thereof (loop 122). In some cases, the cycle is repeated to selectively fill the gap with the material.

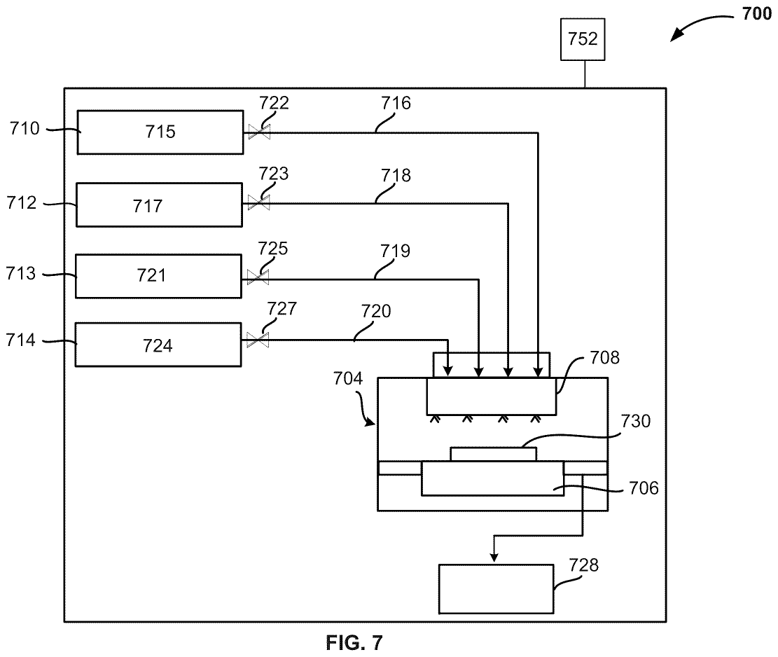

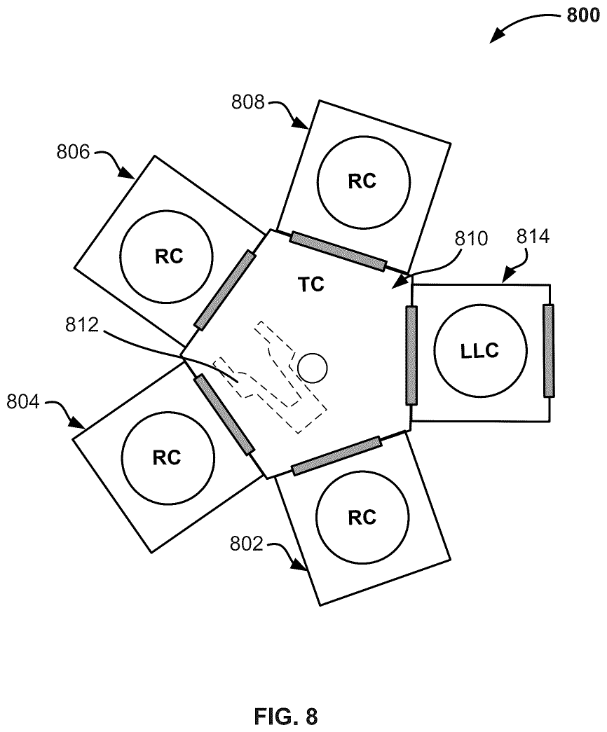

Turning now to FIGS. 7 and 8, exemplary reactor systems 700 and 800 are illustrated. Reactor systems 700 and/or 800 can be used to perform a method as described herein and/or to form a structure as described herein.

Reactor system 700 includes a reaction chamber 704, a susceptor 706 to hold a substrate 730 during processing, a gas distribution system 708 (e.g., a showerhead) to distribute one or more blocking molecules, precursors and/or reactants to a surface of substrate 730, one or more blocking molecules, precursors, or reactant sources 710, 712, and/or 713, and/or a carrier and/or purge gas source 714, fluidly coupled to reaction chamber 704 via respective lines 716, 718, 719 and 720, and respective valves or controllers 722, 723, 725 and 727. Substrate 730 can include a substrate or structure as described herein. A purge/carrier gas 724 from gas source 714 can be flowed to and through reaction chamber 104 to act as a carrier gas, and/or purge or remove any excess blocking molecule, precursor, reactant or other undesired materials from reaction chamber 704. Sources 710, 712, and 713 can include vessels and blocking molecules, a precursor or a reactant as described herein. For example, source 710 can include a vessel and a blocking molecules 715; source 712 can include a vessel and precursor 717; source 713 can include a vessel and a reactant 721. Reactor system 700 can include additional sources. System 700 can also include a vacuum source 728 fluidly coupled to the reaction chamber 704. Vacuum source 728 can be configured to evacuate blocking molecules, precursors, reactants, a purge gas, byproducts, or other materials out of reaction chamber 704.

Reactor system 700 also includes a controller 752. Controller 752 can be configured to perform various functions and/or steps as described herein. Controller 752 can include one or more microprocessors, memory elements, and/or switching elements to perform the various functions. Although illustrated as a single unit, controller 752 can alternatively comprise multiple devices. Controller 752 can be used to control gas flow (e.g., by monitoring flow rates and controlling valves 722, 723, 725 and/or 727), motors, heaters, cooling devices and/or vacuum source 728 to execute various processes (e.g., one or more steps of method 100). Further, when a system includes two or more reaction chambers, as described in more detail below, the two or more reaction chambers can be coupled to the same/shared controller.

FIG. 8 illustrates a reactor system 800 that includes a plurality of reaction chambers 802-808, each or any of which can be an example of reaction chamber 704 in FIG. 7. Reaction chambers 802-808 can be disposed around and/or coupled to a transfer chamber 810 that includes a transfer tool 812 for transferring substrates between reaction chambers 802-808 and a load lock chamber 814 and between reaction chambers 802-808 (e.g., through transfer chamber 810). For example, a substrate 730 can be disposed in different chambers for different steps of a method described herein. For example, one of reaction chambers 802-808 can be used to provide blocking molecules as described herein, another one of reaction chambers 802-808 can be used to provide the precursor and/or reactant, another one of reaction chambers 802-808 can be used for the step of treating, and another one of reaction chambers 802-808 can be used remove blocking molecules. Other configurations are also possible, such that one or more steps of method 100 are performed within a single reaction chamber.

The example embodiments of the disclosure described above do not limit the scope of the invention, since these embodiments are merely examples of the embodiments of the invention, which is defined by the appended claims and their legal equivalents. Any equivalent embodiments are intended to be within the scope of this invention. Indeed, various modifications of the disclosure, in addition to those shown and described herein, such as alternative useful combinations of the elements described, may become apparent to those skilled in the art from the description. Such modifications and embodiments are also intended to fall within the scope of the appended claims.

1. A topology-selective method of depositing material within a gap on a surface of a substrate, the method comprising the steps of:
providing a substrate within a reaction chamber, the substrate comprising the gap on the surface of the substrate, the gap comprising a gap opening width and a gap height;
providing blocking molecules within the reaction chamber, the blocking molecules having a blocking molecule dimension greater than the gap opening width; and
providing a precursor within the reaction chamber, the precursor comprising precursor molecules having a precursor dimension less than the gap opening width,
wherein the blocking molecules inhibit deposition on a top surface of the substrate, relative to a surface within the gap.

2. The method of claim 1, wherein the method comprises a cyclical deposition process, wherein a cycle of the cyclical deposition process comprises:
the providing blocking molecules; and
the providing the precursor.

3. The method of claim 2, wherein the cycle further comprises a purge step between the providing blocking molecules and the providing the precursor.

4. The method of claim 2, wherein the cycle further comprises providing a reactant to the reaction chamber.

5. The method of claim 2, wherein the cycle further comprises, after the providing the precursor, removing blocking molecules from the surface of the substrate.

6. The method of claim 5, wherein the removing blocking molecules is performed at a temperature greater than a temperature during the providing the precursor.

7. The method of claim 2, wherein the cycle is repeated to selectively fill the gap with the material.

8. The method of claim 1, wherein the material comprises metal.

9. The method of claim 8, wherein the metal comprises one or more of a transition metal or a rare earth metal.

10. The method of claim 1, further comprising treating the surface within the gap.

11. The method of claim 10, wherein the treating is performed during a deposition cycle.

12. The method of claim 1, wherein the blocking molecule dimension is greater than 10× a largest dimension of the precursor molecules.

13. The method of claim 1, wherein the blocking molecules comprise a carbene.

14. The method of claim 13, wherein the carbene is a heterocyclic carbene.

15. The method of claim 13, wherein the carbene is an N-heterocyclic carbene.

16. The method of claim 15, wherein the N-heterocyclic carbene is represented by the formula: 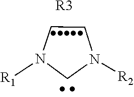
where R₃ is a cyclic group and where each R₁ and R₂ is independently selected from H or a C1-C16 alkyl group.

17. The method of claim 16, where R₁ and R₂ comprise a cyclic group.

18. The method of claim 1, wherein the blocking molecules comprise a surfactant.

19. The method of claim 1, wherein the blocking molecules comprise an alkyl-terminated polyethylene glycol.

20. The method of claim 19, wherein the alkyl-terminated polyethylene glycol is represented by the chemical formula: 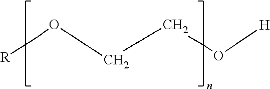
where n ranges from about 50 to about 2000, and
where R is a C1-C10 linear or branched or cyclic hydrocarbon.
